(19) United States
(12) Patent Application Publication
(10) Pub. No.: US 2007/0088993 A1
(43) Pub. Date: Apr. 19, 2007

(54) Memory tester having master/slave configuration

(76) Inventor: Ronald Baker, Raleigh, NC (US)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/252,435

(22) Filed: Oct. 18, 2005

(51) Int. Cl. G11C 29/00

(52) U.S. Cl. 714/718

(57) ABSTRACT

A memory testing system includes a tester interface. The tester interface is configured to couple a tester control driver to a master memory component and a slave memory component, the tester control driver configured for controlling the master memory component and the slave memory component. The tester interface is configured to couple a tester input/output driver to the master memory component and the slave memory component, the tester input/output driver configured for providing first data to write to the master memory component and the slave memory component and for receiving second data read from the master memory component. The slave memory component is configured to receive the second data and compare the second data to third data read from the slave memory component to determine a test result for the slave memory component. The tester input/output driver is configured to compare the first data to the second data to determine a test result for the master memory component.

### BACKGROUND

Memory chips or components are typically tested after fabrication to ensure that the memory components operate properly. A typical memory test includes writing data to the memory component and then reading the data back from the memory component. The data written to the memory component is compared to the data read from the memory component. If the data written to the memory component matches the data read from the memory component, the memory component is a functioning memory component. If the data written to the memory component does not match the data read from the memory component, the memory component is a defective memory component.

Typical memory testers have a limited number of resources available to test memory components, such as drivers, comparators, power supplies, etc. The fewer resources used to test each memory component, the greater the number of memory components that can be tested simultaneously by the memory tester. Some resource limitations of memory testers include the number of driver circuits used to send inputs to the memory component and the number of driver/comparator circuits used to write data to the memory component and judge the output of the memory component.

Typical test methods use at least one group of driver pins and one or more driver/comparators for each memory component. Some memory testers use a group of driver pins to drive two to four components in parallel, but still use separate driver/comparators for each memory component. Typical test systems use separate driver/comparator pins for all memory components, which severely limits the total number of memory components that can be tested simultaneously. Also, a tester driver is limited in the number of memory component inputs it can drive in parallel due to driver output current limitations. Therefore, in typical test systems the number of memory components that can be tested in parallel is limited by the number of driver/comparator pins available and by the drive current capability of the tester driver pins.

### SUMMARY

One embodiment of the present invention provides a memory testing system. The memory testing system includes a tester interface. The tester interface is configured to couple a tester control driver to a master memory component and a slave memory component, the tester control driver configured for controlling the master memory component and the slave memory component. The tester interface is configured to couple a tester input/output driver to the master memory component and the slave memory component, the tester input/output driver configured for providing first data to write to the master memory component and the slave memory component and for receiving second data read from the master memory component. The slave memory component is configured to receive the second data and compare the second data to third data read from the slave memory component to determine a test result for the slave memory component. The tester input/output driver is configured to compare the first data to the second data to determine a test result for the master memory component.

### BRIEF DESCRIPTION OF THE DRAWINGS

Embodiments of the invention are better understood with reference to the following drawings. The elements of the drawings are not necessarily to scale relative to each other. Like reference numerals designate corresponding similar parts.

FIG. 1 is a block diagram illustrating one embodiment of a memory testing system configured to test memory components in parallel.

FIG. 2 is a block diagram illustrating another embodiment of a memory testing system configured to test memory components in parallel.

FIG. 3 is a block diagram illustrating one embodiment of the data path during a write operation from the memory tester to the memory components.

FIG. 4 is a block diagram illustrating one embodiment of the data path during a read operation from the memory components to the memory tester.

FIG. 5 is a block diagram illustrating another embodiment of a memory testing system configured to test memory components in parallel.

### DETAILED DESCRIPTION

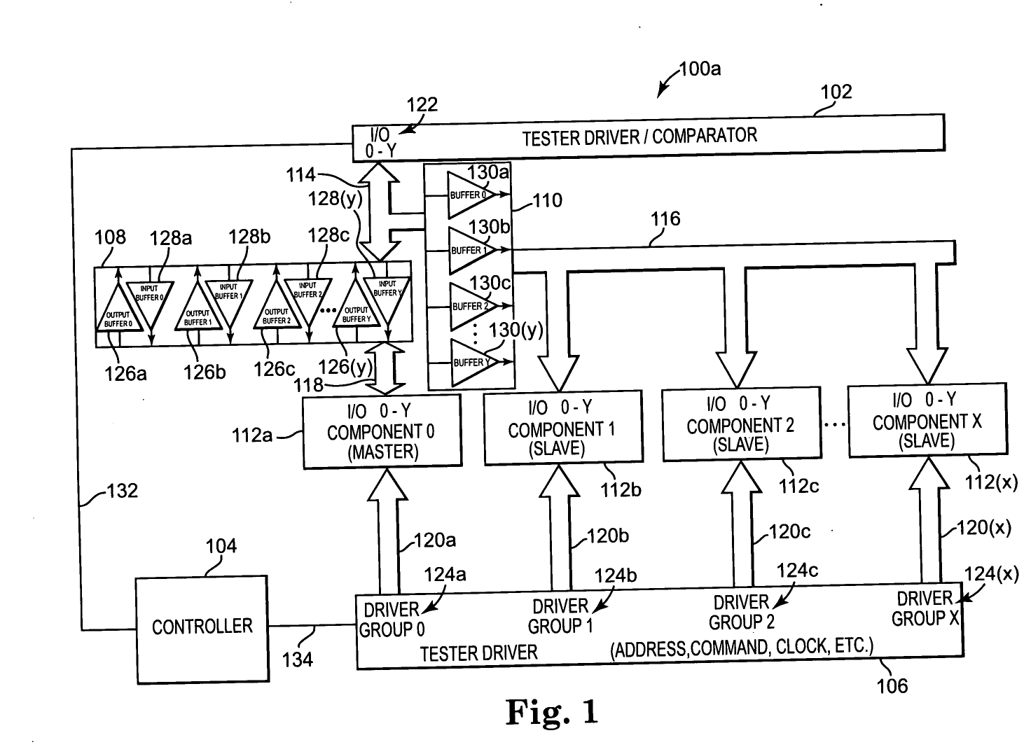

FIG. 1 is a block diagram illustrating one embodiment of a memory testing system 100a configured to test memory components 112 in parallel. Memory testing system 100a is configured to increase the number of memory components 112 that are simultaneously tested in parallel. The number of memory components 112 that are simultaneously tested in parallel is increased by reducing the number of driver/comparators used for some or all of the memory components 112 and by reducing the number of pins required to drive all the memory components 112.

The tester interface includes hardware to greatly reduce the number of tester control drivers and tester input/output drivers used during a memory test. Memory testing system 100a designates one of the parallel memory components 112 as a master memory component and designates the other memory components 112 as slave memory components. The master memory component provides output data to the slave memory components for the slave memory components to judge their own outputs. This method assumes that the memory components 112 have the capability of judging their own output data if provided with input data to which to compare. The slave memory components under test include an internal test mode that if selected enables the memory components to compare their output data to provided input data.

Memory testing system 100a includes a memory tester including tester driver/comparator 102 (i.e., tester input/output driver), tester driver (address, command, clock, etc.) 106 (i.e., tester control driver), and controller 104. Memory testing system 100a also includes a tester interface including master buffer group 108, slave buffer group 110, and the connections between the tester interface and the memory tester. Testing system 100a is configured to test a suitable number “x” of memory components including component zero 112a, component one 112b, and component two 112c through component X 112(x). Memory component zero 112a is designated as the master memory component and memory component one 112b and memory component two 112c through memory component X 112(x) are designated as slave memory components.

Tester driver/comparator 102 is electrically coupled to controller 104 through communication path 132. Controller 104 is electrically coupled to tester driver (address, command, clock, etc.) 106 through communication path 134. Tester driver/comparator 102 includes input/output (I/O) 0-Y pins or pads 122. I/O 0-Y pins 122 are electrically coupled to master buffer group 108 and slave buffer group 110 through communication path 114. Master buffer group 108 is electrically coupled to memory component zero 112a through communication path 118. Slave buffer group 110 is electrically coupled to memory component one 112b through memory component X 112(x) through communication path 116.

Tester driver (address, command, clock, etc.) 106 includes driver group zero output pins or pads 124a, driver group one output pins or pads 124b, and driver group two output pins or pads 124c through driver group X output pins or pads 124(x). Driver group zero output pins 124a are electrically coupled to control inputs of component zero 1 12a through communication path 120a. Driver group one output pins 124b are electrically coupled to control inputs of memory component one 112b through communication path 120b. Driver group two output pins 124c are electrically coupled to control inputs of memory component two 112c through communication path 120c, and driver group X output pins 124(x) are electrically coupled to control inputs of memory component X 112(x) through communication path 120(x).

Master buffer group 108 includes output buffer zero 126a, output buffer one 126b, and output buffer two 126c through output buffer Y 126(y), where “y” equals the number of I/O 0-Y pins 122. Master buffer group 108 also includes input buffer zero 128a, input buffer one 128b, and input buffer two 128cthrough input buffer Y 128(y). Slave buffer group 110 includes buffer zero 130a, buffer one 130b, and buffer two 130c through buffer Y 130(y). There is one buffer for each I/O pin connection between tester driver/comparator 102 and slave memory components 112b-112(x). There is one output buffer 126a-126(y) and one input buffer 128a-128(y) for each I/O pin connection between tester driver/comparator 102 and master memory component zero 112a.

Controller 104 controls the operation of memory testing system 100a including the timing of data and control signals through tester driver/comparator 102 and tester driver (address, command, clock, etc.) 106. Tester driver/comparator 102 writes test data to memory components 112a-112(x) and reads test data from master memory component zero 112a. Tester driver/comparator 102 compares the test data written to memory components 112a-112(x) to test data read from master memory component zero 112a. Tester driver (address, command, clock, etc.) 106 provides address command and clock signals to memory components 112a-112(x) for writing test data to and reading test data from memory components 112a-112(x). In one embodiment, memory components 112a-112(x) are random access memories (RAMs), such as dynamic random access memories (DRAMs), synchronous dynamic random access memories (SDRAMs), static random access memories (SRAMs), pseudo-static random access memories (PSRAM), or another suitable type of RAM.

In operation, component zero 112a is designated as the master memory component and is configured to operate in the normal operating mode. Memory components 112b-112(x) are designated as slave memory components and are configured to operate in a test operating mode. In the test operating mode, memory components 112b-112(x) internally compare their output data to provided input data to determine a test result.

Controller 104 controls tester driver (address, command, clock, etc.) 106 and tester driver/comparator 102 to write test data to master memory component zero 112a through master buffer group 108 and to slave memory components 112b-1 12(x) through slave buffer group 110. Master buffer group 108 and slave buffer group 110 increase the current drive capability of tester driver/comparator 102 to allow greatly increased parallelism from one set of tester driver/comparator pins 122 with little timing skew between write test data for memory components 112a-112(x).

After the test data has been written to memory components 112a-112(x), controller 104 controls tester driver/comparator 102 and tester driver (address, command, clock, etc.) 106 to read the data stored in memory components 112a-112 (x). The test data read from master memory component zero 112a is passed through output buffers 126a-126(y) to I/O 0-Y pins 122 of tester driver/comparator 102. The test data read from master memory component zero 112a is also passed to slave memory components 112b-112(x) through output buffers 126a-126(y) and slave buffers 130a-130(y).

Tester driver/comparator 102 compares the test data that was written to master memory component zero 112a with the test data read from master memory component zero 112a to determine a test result. If the test data written to master memory component zero 112a equals the test data read from master memory component zero 112a, master memory component zero 112a passes the test indicating a functional memory component. If the test data written to master memory component zero 112a does not match the data read from master memory component zero 112a, then master memory component zero 112a fails the test indicating a defective memory component.

With slave memory components 112b-112(x) in a test operating mode, each slave memory component 112b-112(x) internally compares its read test data to the test data passed to the slave memory component from master memory component zero 112a. If the test data passed from master memory component 112a matches the read test data of the slave memory component 112b-112(x), then the slave memory component 112b-112(x) passes the test indicating a functional memory component. If the test data passed from master memory component zero 112a does not match the read test data of the slave memory component 112b-112(x), then the slave memory component 112b-112(x) fails the test indicating a defective memory component. In one embodiment, a chip select pin of each slave memory component is toggled to output the test result for each slave memory component to the memory tester.

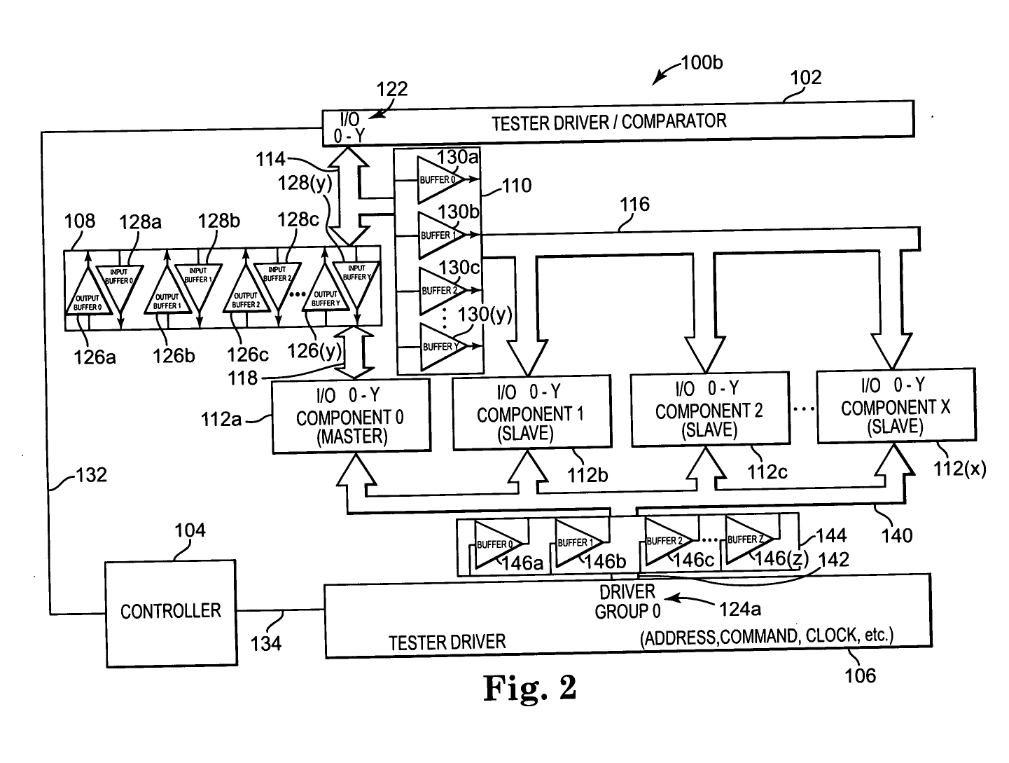

FIG. 2 is a block diagram illustrating another embodiment of a memory testing system 100b configured for testing memory components 112 in parallel. Memory testing system 100b is similar to memory testing system 100a except that memory testing system 100b includes a tester interface including buffer group 144. Buffer group 144 is electrically coupled to driver group zero pins 124a of tester driver (address, command, clock, etc.) 106 through communication path 142. Buffer group 144 is electrically coupled to memory components 112a-112(x) through communication path 140. Buffer group 144 includes buffer zero 146a, buffer one 146b, and buffer two 146c through buffer Z 146(z), where z is an integer indicating the number of address, command, and clock pins of tester driver group zero 124a. Buffer group 144 increases the drive capability of driver group zero 124a to allow increased parallelism from one set of tester driver pins with little timing skew between control signals for memory components 112a-112(x). Memory testing system 100b operates similarly to memory testing system 100a.

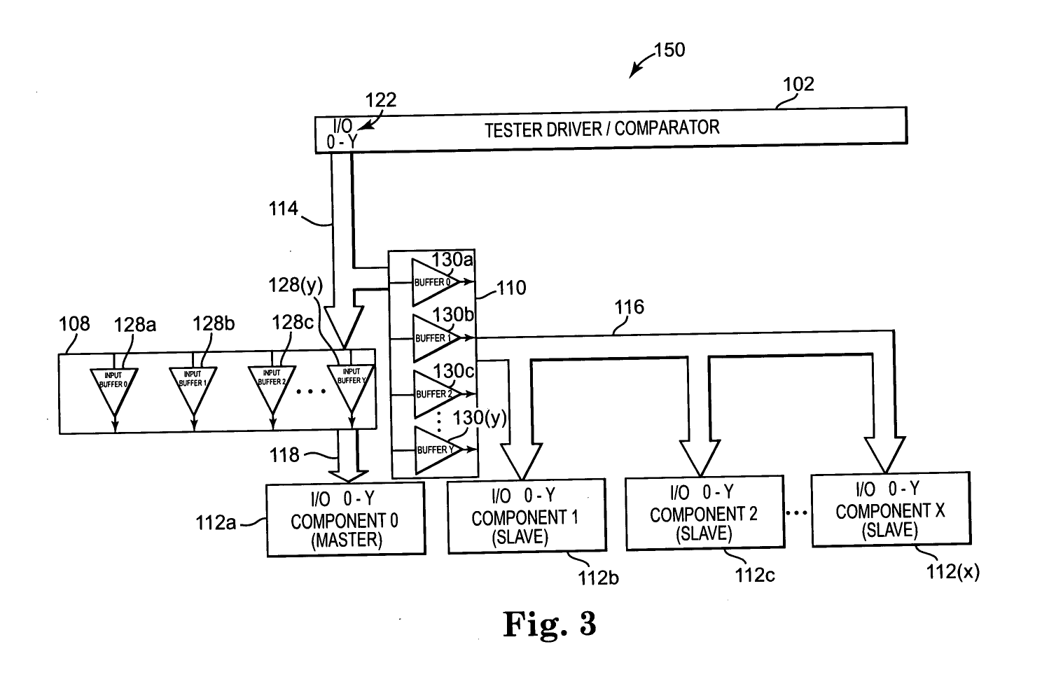

FIG. 3 is a block diagram illustrating one embodiment of the data path 150 during a write operation from tester driver/comparator 102 to memory components 112 for memory testing system 100a or 100b. During a write operation, test data is written by tester driver/comparator 102 through I/O 0-Y pins 122 to master buffer group 108 and slave buffer group 110 through communication path 114. The test data passes through input buffers 128a-128 (y) and communication path 118 to master memory component zero 112a. The 1/O 0-Y pins of master memory component zero 112a receive the test data and the test data is written to the master memory component. The test data also passes through buffers 130a-130(y) and communication path 116 to slave memory components 112b-112(x). The I/O 0-Y pins of slave memory components 112b-112(x) receive the test data and the test data is written to the slave memory components. In one embodiment, the number of memory components X under test is 4, 8, 16, 64, or another suitable number of memory components.

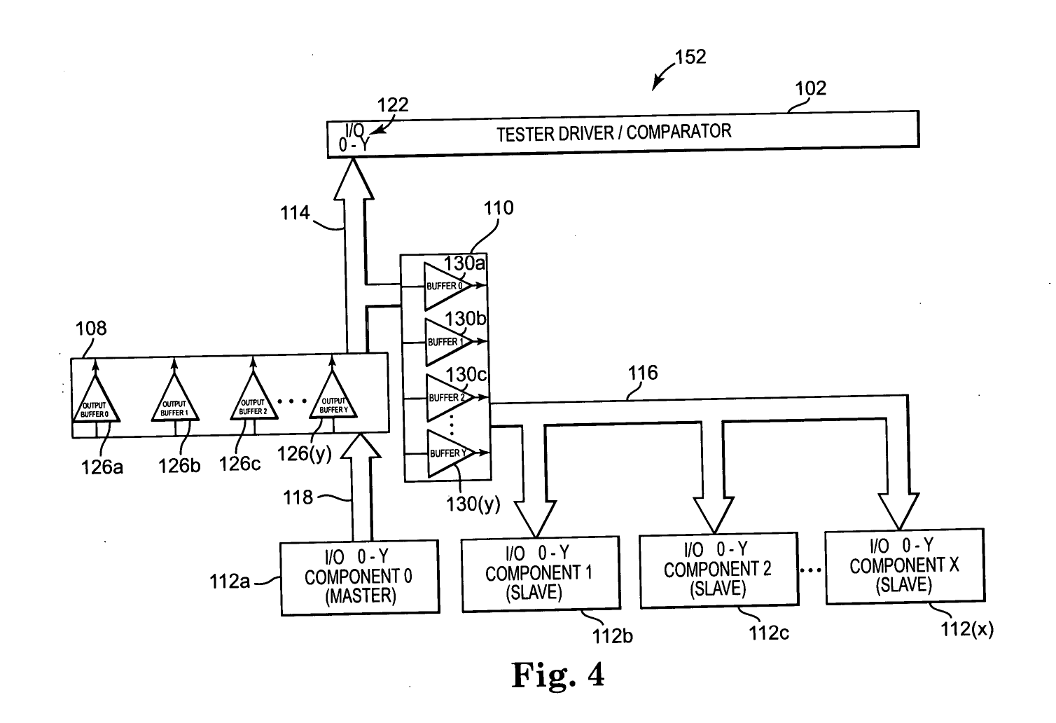

FIG. 4 is a block diagram illustrating one embodiment of a data path 152 during a read operation from memory components 112 to tester driver/comparator 102 for memory testing system 100a or 100b. During a read operation, test data is read from master memory component zero 112a and passed to output buffers 126a-126(y) through communication path 118. The test data read from master memory component zero 112a passes through output buffers 126a-126(y) and communication path 114 to buffers 130a-130(y) and to I/O 0-Y pins 122 of tester driver/comparator 102. The read test data passes through buffers 130a- 130(y) and communication path 116 to the I/O 0-Y pins of slave memory components 112b-112(x).

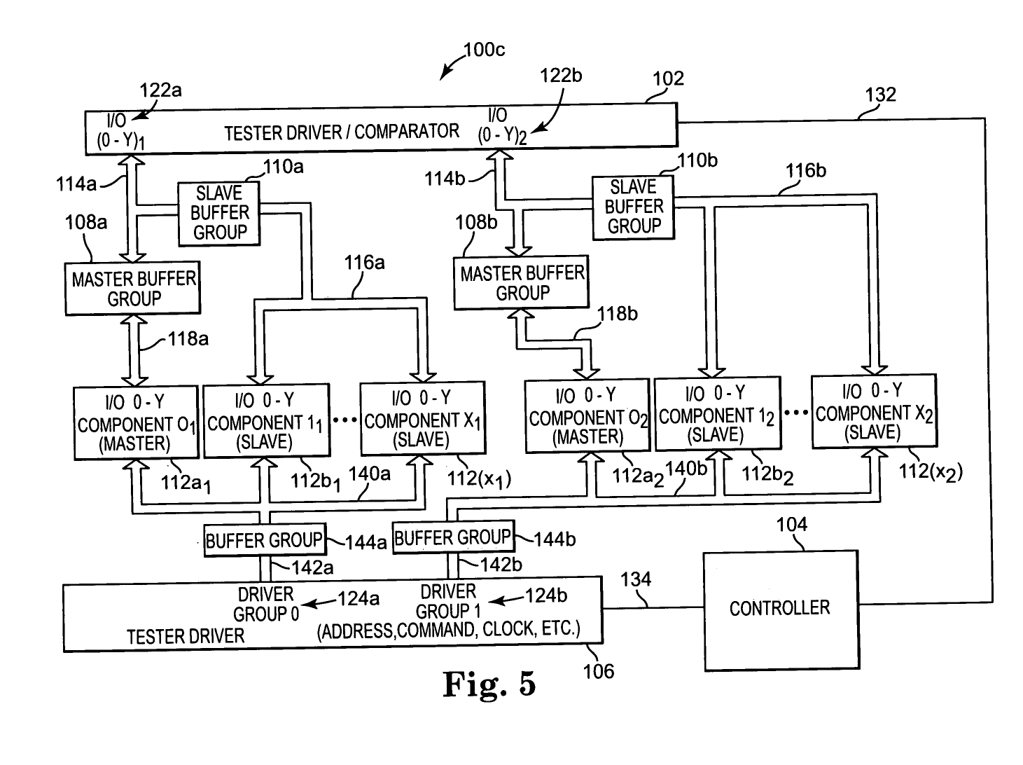

FIG. 5 is a block diagram illustrating another embodiment of a memory testing system 100c configured for testing memory components 112 in parallel. Memory testing system 100c includes similar components to memory testing system 100a and 100b. Memory testing system 100c includes a memory tester including tester driver/comparator 102, controller 104, and tester driver (address, command, clock, etc.) 106. Memory testing system 100c also includes a tester interface including master buffer groups 108a and 108b, slave buffer groups 110a and 110b, and buffer groups 144a and 144b. Tester driver/comparator 102 includes I/O (0-Y)₁ pins 122a and I/O (0-Y)₂ pins 122b. Tester driver (address, command, clock, etc.) 106 includes driver group zero 124a and driver group one 124b. Memory testing system 100c is configured to test memory components 112a₁-112(x₁) and memory components 112a₂-112(x₂).

I/0 (0-Y)₁pins 122a of tester driver/comparator 102 are electrically coupled to master buffer group 108a and slave buffer group 110a through communication path 114a. Master buffer group 108a is electrically coupled to master memory component zero₁112a₁ through communication path 118a. Slave buffer group 110a is electrically coupled to slave memory components 112b₁-112(x₁) through communication path 116a. Memory components 112a₁-112 (x₁) are electrically coupled to buffer group 144a through communication path 140a. Buffer group 144a is electrically coupled to driver group zero pins 124a of tester driver (address, command, clock, etc.) 106 through communication path 142a.

I/O (0-Y)2 pins 122b of tester driver/comparator 102 are electrically coupled to master buffer group 108b and slave buffer group 110b through communication path 114b. Master buffer group 108b is electrically coupled to master memory component zero₂ 112a₂ though communication path 118b. Slave buffer group 110b is electrically coupled to slave memory components 112b₂-112 (x₂) through communication path 116b. Memory components 112a₂-112(x₂) are electrically coupled to buffer group 144b through communication path 140b. Buffer group 144b is electrically coupled to driver group one pins 124b of tester driver (address, command, clock, etc.) 106 through communication path 142b. Tester driver/comparator 102 is electrically coupled to controller 104 through communication path 132. Controller 104 is electrically coupled to tester/driver (address, command, clock, etc.) 106 through communication path 134.

Memory testing system 100c includes two master memory components including memory component zero₁ 112a₁ and memory component zero₂ 112a₂. Each master memory component 112a₁ and 112a₁ is associated with a group of slave memory components 112b₁-112(x₁) and 112b₂-112(x₂), respectively. Each master memory component and slave memory component group operates similarly to the single master and slave memory component groups of memory testing systems 100a and 100b. In one embodiment, any suitable number of master memory component and slave memory component groups are tested in parallel by memory testing system 100c.

Embodiments of the present invention provide a memory tester configuration including master and slave memory components and buffers for greatly increasing parallelism from one set of tester driver (address, command, clock, etc.) pins and one set of tester driver/comparator pins. Embodiments of the invention enable a memory tester designed to be a bench test system for testing one memory component at a time to test a plurality of memory components in parallel simultaneously. Embodiments of the invention reduce the cost of the test system by increasing the number of memory components that can be tested in parallel.

What is claimed is:

1. A memory testing system comprising:
a tester interface configured to:
couple a tester control driver to a master memory component and a slave memory component, the tester control driver configured for controlling the master memory component and the slave memory component;
couple a tester input/output driver to the master memory component and the slave memory component, the tester input/output driver configured for providing first data to write to the master memory component and the slave memory component and for receiving second data read from the master memory component;
wherein the slave memory component is configured to receive the second data and compare the second data to third data read from the slave memory component to determine a test result for the slave memory component; and
wherein the tester input/output driver is configured to compare the first data to the second data to determine a test result for the master memory component.

2. The memory testing system of claim 1, wherein the tester interface further comprises:
a group of input and output buffers configured to couple the tester input/output driver to the master memory component.

3. The memory testing system of claim 1, wherein the tester interface further comprises:
a group of buffers configured to couple the tester input/output driver to the first slave memory component.

4. The memory testing system of claim 1, wherein the tester interface further comprises:
a group of buffers configured to couple the tester control driver to the master memory component and the slave memory component to control the master memory component and the slave memory component in parallel through a single group of tester control driver pins.

5. The memory testing system of claim 1, wherein the tester control driver and the tester input/output driver are part of a bench test system.

6. A memory testing system comprising:
a tester control driver configured for controlling a first master memory component and a first plurality of slave memory components; and
a tester input/output driver configured for providing first data to the first master memory component and each first slave memory component and for receiving second data from the first master memory component;
wherein each first slave memory component is configured to receive the second data from the first master memory component and compare the second data to third data read from each first slave memory component to provide a test result for each first slave memory component; and
wherein the tester input/output driver is configured to compare the first data to the second data to provide a test result for the first master memory component.

7. The memory testing system of claim 6, further comprising:
a group of input and output buffers between the tester input/output driver and the master memory component.

8. The memory testing system of claim 6, further comprising:
a group of buffers between the tester input/output driver and each first slave memory component to provide the first data to the first master memory component and each first slave memory component through a single group of tester input/output driver pins.

9. The memory testing system of claim 6, further comprising:
a group of output buffers between the tester control driver and the master memory component and the first plurality of slave memory components to control the master memory component and each slave memory component in parallel through a single group of tester control driver pins.

10. The memory testing system of claim 6, wherein the tester control driver is configured for controlling a second master memory component and a second plurality of slave memory components;
wherein the tester input/output driver is configured for providing the first data to the second master memory component and each second slave memory component and for receiving fourth data from the second master memory component;
wherein each second slave memory component is configured to receive the fourth data from the second master memory component and compare fifth data read from each second slave memory component to the fourth data to provide a test result for each second slave memory component; and
wherein the tester input/output and comparator circuit is configured to compare the first data to the fourth data to provide a test result for the second master memory component.

11. The memory testing system of claim 6, wherein the tester control driver and the tester input/output driver are part of a bench test system.

12. A system for testing components comprising:
means for writing first data to a master component and a slave component in parallel through a single group of input/output pins;
means for reading second data out of the master component and passing the second data to the slave component;
means for comparing the first data to the second data to determine a test result for the master component; and
means for reading third data from the slave component and internal to the slave component comparing the third data to the second data to determine a test result for the slave component.

13. The system of claim 12, further comprising:
means for outputting the test result for the slave component from the slave component.

14. The system of claim 12, further comprising:
means for placing the slave component in a test mode.

15. The system of claim 12, wherein the master component comprises a dynamic random access memory and the slave component comprises a dynamic random access memory.

16. The system of claim 12, wherein the master component comprises a static random access memory and the slave component comprises a static random access memory.

17. A method for testing memory components, the method comprising:
writing first data to a master memory component and a slave memory component in parallel through a single group of tester input/output driver pins;
reading second data from the master memory component and passing the second data to the tester input/output driver through the single group of tester input/output driver pins;
passing the second data from the master memory component to the slave memory component;
comparing the first data to the second data in the tester input/output driver to determine a test result for the master memory component; and
reading third data from the slave memory component and internal to the slave memory component comparing the third data to the second data to determine a test result for the slave memory component.

18. The method of claim 17, wherein writing first data to the master memory component comprises writing first data to the master memory component through a group of input buffers between the tester input/output driver and the master memory component.

19. The method of claim 17, wherein passing the second data to the tester input/output driver comprises passing the second data to the tester input/output driver through a group of output buffers between the tester input/output driver and the master memory component.

20. The method of claim 17, wherein passing the second data from the master memory component to the slave memory component comprises passing the second data to the slave memory component through a group of buffers between the master memory component and the slave memory component.

21. The method of claim 17, further comprising:
controlling the master memory component and the slave memory component in parallel through a single group of tester control driver pins.

22. The method of claim 21, wherein controlling the master memory component and the slave memory component in parallel comprises controlling the master memory component and the slave memory component through a group of buffers between the tester control driver and the master memory component and the slave memory component.

23. A method for testing memory components, the method comprising:
writing first data to a first master memory component and at least two first slave memory components in parallel through a first single group of tester input/output driver pins;
reading second data from the first master memory component and passing the second data to the tester input/output driver through the first single group of tester input/output driver pins;
passing the second data from the first master memory component to the at least two first slave memory components;
comparing the first data to the second data in the tester input/output driver to determine a test result for the first master memory component; and
reading third data from each of the at least two first slave memory components and internal to each of the at least two first slave memory components comparing the third data to the second data to determine a test result for each of the at least two first slave memory components.

24. The method of claim 23, wherein writing first data to the first master memory component comprises writing first data to the first master memory component through a group of input buffers between the tester input/output driver and the first master memory component.

25. The method of claim 23, wherein passing the second data to the tester input/output driver comprises passing the second data to the tester input/output driver through a group of output buffers between the tester input/output driver and the master memory component.

26. The method of claim 23, wherein passing the second data from the first master memory component to the at least two first slave memory components comprises passing the second data to the at least two first slave memory components through a group of buffers between the first master memory component and the at least two first slave memory components.

27. The method of claim 23, further comprising:
writing the first data to a second master memory component and at least two second slave memory components in parallel through a second single group of tester input/output driver pins;
reading fourth data from the second master memory component and passing the fourth data to the tester input/output driver through the second single group of tester input/output driver pins;
passing the fourth data from the second master memory component to the at least two second slave memory components;
comparing the first data to the fourth data in the tester input/output driver to determine a test result for the second master memory component; and
reading fifth data from each of the at least two second slave memory components and internal to each of the at least two second slave memory components comparing the fifth data to the fourth data to determine a test result for each of the at least two second slave memory components.
